(19) United States
(12) Patent Application Publication
(10) Pub. No.: US 2003/0135990 A1
(43) Pub. Date: Jul. 24, 2003

(54) Pick and place device, pick and place system and method of fitting substrates with components

(76) Inventors: Martin Pruefer, Munich (DE); Harald Stanzl, Munich (DE)

Correspondence Address: HARNESS, DICKEY & PIERCE, P.L.C., P.O.BOX 8910, RESTON, VA, 20195, US

(21) Appl. No.: 10/216,203

(22) Filed: Aug. 12, 2002

(30) Foreign Application Priority Data
Jan. 18, 2002 (DE) 10201879.0

(51) Int. Cl. B23P 19/00; H05K 3/30

(52) U.S. Cl. 29/739; 29/740; 29/834

(57) ABSTRACT

A pick and place device, a pick and place system and a method of fitting substrates with components are provided, in which feed devices having a plurality of feed modules and a corresponding plurality of collection points on opposite sides of the feed devices in each case have at least one pick and place area, pick and place heads being assigned to the pick and place areas, by way of which components can be removed alternatingly and/or simultaneously from the collection points of the feed devices in order to be positioned on substrates which are arranged in the pick and place areas.

The present application hereby claims priority under 35 U.S.C. Section 119 on German Patent application number 10201879.0 filed Jan. 18, 2002, the entire contents of which are herein incorporated by reference.

### FIELD OF THE INVENTION

The invention generally relates to a pick and place device for fitting substrates with components, a pick and place system and a method of fitting substrates with components.

### BACKGROUND OF THE INVENTION

To fit substrates with electrical and/or electronic components, such as integrated circuits, resistors, capacitors, relays, plug connectors or the like, a large number of devices are known. For example, DE 4301585 A1 discloses the practice of arranging pick and place areas along a transport path on opposite sides of the transport path for substrates and arranging feed devices for the pick and place areas at the side of the pick and place areas. The substrates are transferred from the transport path to the pick and place areas by way of transfer devices. The direction of movement of the pick and place head runs parallel to the transport path. Arranged upstream and downstream of the pick and place areas, in the direction of the transport path, are feed devices for components. In this way, the number of components which can be put down on the substrate to be populated is increased.

Furthermore, U.S. Pat. No. 5,778,524 discloses a pick and place device for fitting substrates with components in which two pick and place areas are arranged along one side of a transport path, at the side of the transport path, immediately following each other in the transport direction of the transport path. According to U.S. Pat. No. 5,778,524, feed devices are arranged upstream and downstream in the transport direction of the two pick and place areas arranged adjacent to each other, from which feed devices the components to be fitted can be removed. This pick and place device is used to reduce considerably the time during which the pick and place heads cannot pick and place, because of the loading or unloading operation of the substrates into or from the pick and place areas.

While, in the past, the focus in the development of pick and place devices was to be able to fit as many components as possible to a substrate in the shortest possible time, the pick and place devices were configured in such a way that a pick and place area is assigned the greatest possible number of feed devices and also a plurality of pick and place heads. Furthermore, a plurality of substrate holders were provided in a pick and place area, so that, for example, two substrates could be populated simultaneously in one pick and place area.

In the meantime, however, with regard to the components that can be fitted to a substrate in a predefined time, the pick and place performance of the pick and place devices appears to have approached a limiting value. With regard to the maximum achievable pick and place performance, the endeavors have therefore been directed at fitting as many components as possible to substrates within a predetermined time on a predefined floor area.

### SUMMARY OF THE INVENTION

An embodiment of the invention is therefore based on an object of specifying a pick and place device for populating substrates. Moreover, an embodiment of the present invention is directed toward a method of fitting substrates with components in which the area-specific pick and place performance is increased.

An object according to an embodiment of the invention may be achieved by a pick and place device having the features as claimed in claim 1, a pick and place system having the features as claimed in claim 7 and a method having the features as claimed in claim 8. Preferred refinements of embodiments of the invention are claimed in the dependent claims.

An advantage of the invention resides in the fact that the focal point of the consideration of the pick and place device according to the invention and of the method according to the invention of fitting substrates with components is not, as used in many approaches in the past, the pick and place area or the substrate as such, instead that now the feed devices are put at the center of the considerations for increasing the performance.

Therefore, according to the invention, starting from one or more feed devices, a plurality of pick and place areas may be arranged around this feed device. The reason for this is that of all the components of a pick and place device, the feed devices are those which make up a considerable proportion of the machine floor area. In order to increase the area-specific pick and place performance of a pick and place device, the invention therefore provides optimum conditions in order to take as many components as possible from the feed device or devices within a predefined time. These components removed are then placed on substrates in appropriate pick and place areas. However, in this case the placement/positioning of the components at the predetermined positions on the substrates is not time-critical, but the collection of the components from the feed devices. According to the invention, therefore, the components are taken simultaneously or immediately successively from the feed device or devices by way of at least two pick and place heads.

Therefore, the pick and place device according to the invention has at least one feed device for feeding the components to at least one collection position. Pick and place areas are arranged on opposite sides of the feed device. Provided in each pick and place area is at least one pick and place head which can be moved at least in one pick and place direction, by which in each case the components can be taken from the collection position. Furthermore, at least one transport path is provided, along which the substrates can be transported in a transport direction. Assigned to each pick and place area is in each case at least one substrate holder, from which the substrates to be populated can be picked up, it being possible in each case, by way of the pick and place heads, for the removed components to be transported to a predetermined pick and place position and set down there on the substrates held by the substrate holders. The direction of movement primarily described by the pick and place heads between the collection positions and the fitting positions constitutes the pick and place direction or else the main direction of movement.

By centralizing the pick and place device on the feed device or the feed devices and assigning a plurality of pick and place areas and a plurality of pick and place heads to the feed devices or the feed device, the invention ensures that the maximum number of components can be removed from the feed device or the feed devices within a predefined time. Since the feed device makes up a considerable proportion of the floor area of a pick and place device, the area-specific pick and place performance of the pick and place device is increased considerably in this way.

The substrate holders can be designed, for example, as parts of the transport path or as separate holding devices for the substrates, which can be moved laterally toward the transport path.

The pick and place areas can be arranged at the side of the transport path, and the pick and place direction can correspond to the transport direction, that is to say the direction of movement of the pick and place heads is then substantially parallel to the transport direction of the substrates along the transport path. In this solution, the substrate holders are designed such that they can move between the transport path and the pick and place areas. Therefore, the substrates can be transported from the transport path to the pick and place areas by way of the substrate holders. For example, this movement of the substrate holders relative to the pick and place areas is also used as a movement in an axis for positioning the substrates during population.

It is also possible to provide more than one transport path, in each case one of the transport paths running through respectively one of the pick and place areas. In this case, the substrate holders are formed by transport elements on the transport path, and the pick and place direction runs substantially at right angles to the transport direction, that is to say the direction of movement of the pick and place heads is substantially at right angles to the transport direction. The other direction of movement, required for positioning the components on the substrates, is implemented by moving the substrates in the transport direction.

For example, the feed device has a plurality of feed modules arranged parallel to one another. This makes it possible to fit a very large number of different components to the substrates with a single pick and place device.

The pick and place heads used are in particular multiple pick and place heads, for example turret pick and place heads or inline pick and place heads, such as matrix pick and place heads or row pick and place heads. Using multiple pick and place heads it is possible firstly to pick up a plurality of components, which can then be placed on the substrates either immediately successively or else simultaneously. In addition, the picking-up action can be carried out successively with short time intervals or simultaneously. It is also possible to design the pick and place heads to be movable substantially at right angles to the pick and place direction, in addition to the pick and place direction. In this way, corrections to the placement position or the collection position of the components can be carried out at right angles to the pick and place direction, which means that flexible fitting is possible.

According to the invention, a pick and place system is also provided which has a plurality of pick and place devices according to the invention arranged along a transport path. In this case, the feed devices are in each case arranged between two pick and place areas and, by way of the pick and place heads of the pick and place areas each facing the feed devices, components can be removed from the feed devices and positioned on the substrates. As a result of lining up a plurality of pick and place devices according to the invention in a row, synergistic effects are possible to the effect that, by way of the pick and place heads, in each case a larger number of pick and place areas and/or feed devices, which lie in the range of movement of the respective pick and place heads, can be served, so that with a given floor area of the pick and place system, higher flexibility and a higher pick and place speed can be reached.

In the method according to the invention of fitting substrates with components, by way of the pick and place device according to the invention or by way of the pick and place system according to the invention, in each case alternatingly in the case of one feed device or else simultaneously in the case of a plurality of feed devices, components are removed from the collection position or positions of the feed devices and positioned at the predetermined positions on the substrates. According to the invention, this makes it possible to remove a maximum number of components from one or more feed devices at a predetermined time in advance and to position them at predetermined positions on the substrates. This ensures a high area-specific pick and place performance.

It is also possible, in the case of the pick and place system according to the invention, by way of those pick and place heads which are assigned to two adjacent feed devices, to position components alternatingly at the predetermined positions on a substrate located between the two feed devices. In this way, in addition to the alternating removal of components from the feed devices, alternating fitting within the pick and place areas arranged between adjacent feed devices is also possible. As a result, still higher flexibility and area performance

$$area performance = ( \frac{Fitting performance}{Area} ) c an be achieved .$$

### BRIEF DESCRIPTION OF THE DRAWINGS

The invention will be explained in more detail with reference to the drawings, in which:

FIG. 1 shows a schematic view of a pick and place device according to the prior art;

FIG. 2 shows a preferred embodiment of the pick and place device according to the invention;

FIG. 3 shows another preferred embodiment of the pick and place device according to the invention; and

FIG. 4 shows a further preferred embodiment of the pick and place device according to the invention.

### DETAILED DESCRIPTION OF THE PREFERRED EMBODIMENTS

FIG. 1 reveals a schematic view of a pick and place device according to the prior art. In this case, two substrates 20-1 and 20-2 to be populated are in each case arranged in a pick and place area along a transport path 25-1 and 25-2 and can be transported in the transport direction Y. In each case a plurality of feed modules 10-1 and 10-2 is arranged at the side of the transport paths 25-1 and 25-2. Each of the feed modules 10-1 and 10-2 has a collection position 15-1 and 15-2. Above the feed modules, the transport paths and the substrates, pick and place heads 30-1 and 30-2 are arranged such that they can be moved in each case in the direction X and in the direction Y over the pick and place areas and the feed devices. According to the prior art, in each case one pick and place head 30-1 or 30-2 is moved over the collection points 15-1 or 15-2 of the corresponding feed modules 10-1 or 10-2 in order to remove the corresponding components and place them on one of the two substrates 20-1 or 20-2. Here, the arrows B identify the minimum required travel of the pick and place heads. In this case, however, there is the disadvantage that the area required by the aforementioned pick and place device is very high. Therefore, the pick and place performance which can be achieved within a specific time on a predefined area is limited.

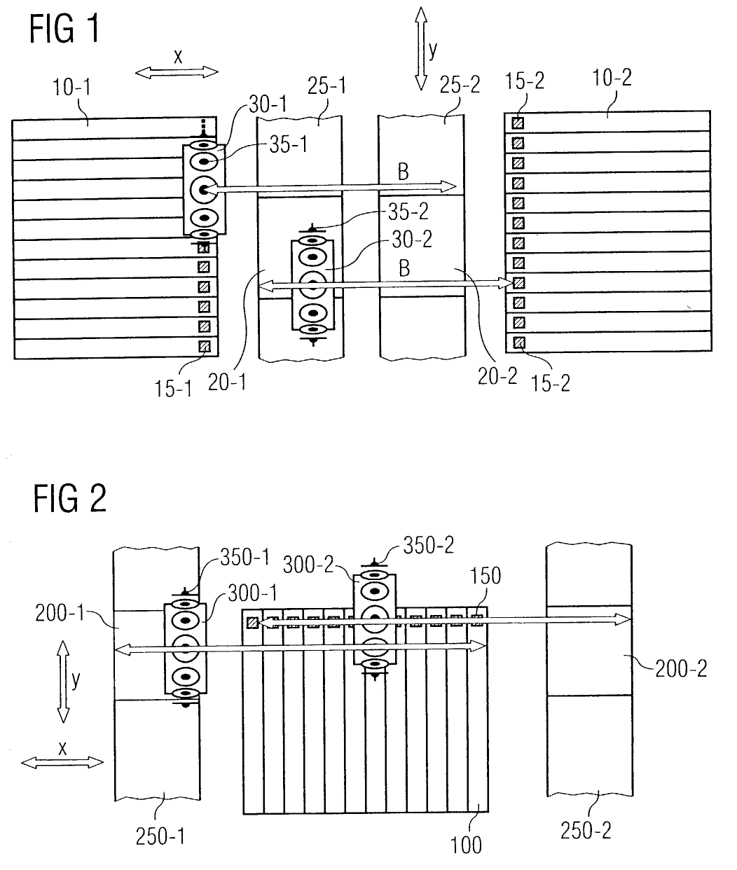

FIG. 2 reveals a schematic view of a preferred embodiment of the pick and place device according to the invention. The pick and place device according to the invention has a plurality of feed modules 100, which are arranged in relation to a feed device, around which the remaining components of the pick and place device are arranged in such a way that the area-specific pick and place performance of the pick and place device according to the invention is maximized. For this purpose, on the sides of the feed device opposite each other in the direction X, in each case there are arranged pick and place areas within which the substrates 200-1 and 200-2 can be populated. For this purpose, pick and place heads 300-1 and 300-2 are additionally used, each having grippers 350-1 and 350-2. The pick and place heads 300-1 and 300-2 are arranged such that they can be moved in the direction X over the pick and place areas with the substrates and over the collection points 150 of the plurality of feed modules of the feed device. By way of the grippers 350-1 and 350-2, components can be removed from the feed modules 100 at the collection points 150 and, by moving the pick and place heads 300-1 and 300-2 in the direction X, can be set down at predetermined positions on the substrates 200-1 and 200-2. In this case, the substrates 200-1 and 200-2 can be moved on respective transport paths 250-1 and 250-2, which run through the pick and place areas and extend along those sides of the feed device on which the pick and place areas are arranged. The transport paths run substantially at right angles to the direction X.

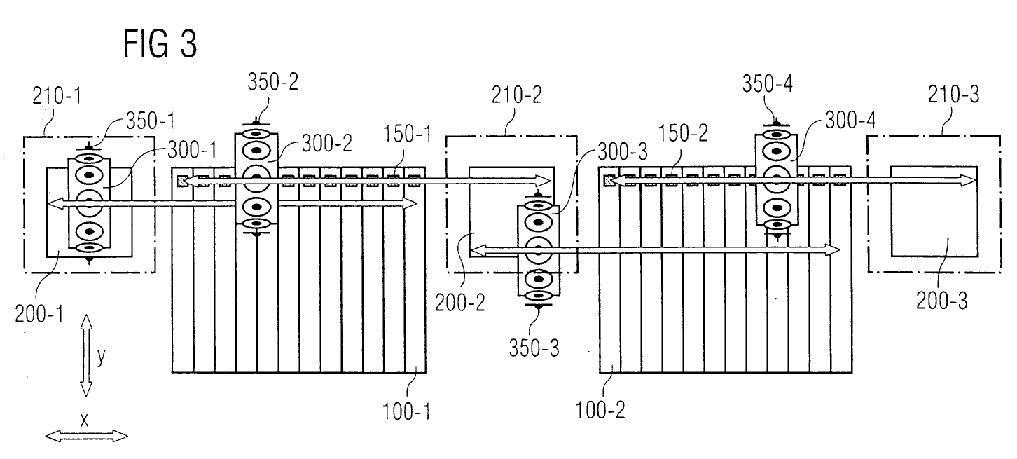

FIG. 3 reveals another preferred embodiment of the pick and place device according to the invention. In this case, pick and place areas 210-1, 210-2 and 210-3 are in each case arranged on opposite sides of the feed devices, on the side of a first feed device having a plurality of feed modules 100-1 and a corresponding plurality of collection points 150-1, and also a second feed device having a plurality of feed modules 100-2 and a corresponding plurality of collection points 150-2. In each pick and place area there may be a substrate 200-1, 200-2 and 200-3, which can be transported there by way of a transport path, not shown.

Furthermore, FIG. 3 shows that the transport paths can in each case be arranged to run in the direction X or in the direction Y. By way of the pick and place heads 300-1, 300-2, 300-3, 300-4 respectively assigned to the pick and place areas 210-1, 210-2 and 210-3, components can be removed from the corresponding collection points 150-1 and 150-2 and positioned on the substrates 200-1, 200-2 and 200-3. In this case, it is theoretically possible to reach all collection points and substrates by way of each pick and place head. For this purpose, appropriate spacings of the movement axes of the pick and place heads in the direction Y are required. In order to keep these small, in particular the pick and place heads 300-1 and 300-4 are assigned exclusively to the pick and place areas 210-1 and 210-3 arranged on the outside of the pick and place device, while the pick and place heads 300-2 and 300-4 can be used to pick and place alternatingly in the pick and place area 210-2 between the first feed device and the second feed device.

In the case of transport paths which are arranged in the direction X, substrate holders may additionally be necessary, by way of which the substrates can be removed from the transport path and fed to the pick and place areas 210-1 and 210-2 and also 210-3. In this case, substrates can also be transported along the transport path past the pick and place areas 210-1, 210-2 and 210-3 while placement is simultaneously being carried out in these pick and place areas. This ensures high flexibility. In particular, it is ensured that components are removed by the feed devices at the highest possible cycle rate, since the feed devices are in each case arranged between two pick and place areas and in each case components are removed from a pick and place device by at least two pick and place heads.

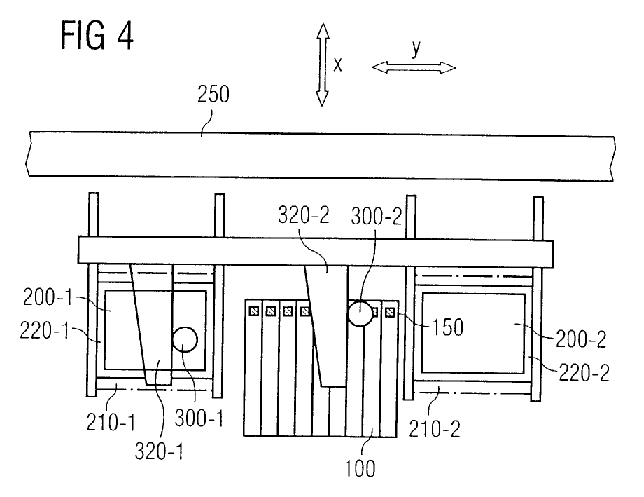

FIG. 4 reveals a further preferred embodiment of the pick and place device according to the invention. Arranged along a transport path 250 is a feed device including a plurality of feed modules 100 having a corresponding plurality of collection points 150. In the transport direction Y of the transport path 250, pick and place areas 210-1 and 210-2 are arranged at the side of the feed device. Each pick and place area is assigned a substrate holder 220-1 or 220-2, by way of which in each case substrates 200-1 or 200-2 can be transported from the transport path into the respective pick and place areas 210-1 and 210-2. Pick and place heads 300-1 and 300-2 are arranged such that they can be moved parallel to the transport path 250. The pick and place heads are in each case fixed to a portal 320-1 and 320-2. Along the portal, they can be moved in the direction X, it being possible for the portals 320-1 and 320-2 to be moved in the direction Y together with the pick and place heads 300-1 and 300-2. The direction X is in particular at right angles to the direction Y. The two pick and place heads 300-1 and 300-2 can in each case be moved over the collection points 150 of the plurality of feed modules 100 of the feed device and from there can remove components which are to be positioned at predetermined positions on the substrates 200-1 and 200-2.

By lining up a plurality of pick and place devices according to the invention in accordance with the further preferred embodiment of the invention, as can be seen from FIG. 4, it is possible to provide a pick and place device according to the other preferred embodiment of the invention according to FIG. 3.

Further combinations of the pick and place device according to the invention are also possible. In particular, it is possible to provide appropriate feed devices having a plurality of feed modules and collection points on both sides of the transport path 250, and also pick and place areas and pick and place heads assigned to the latter arranged at the side of the feed devices. It is also possible to design the transport path as a multiple transport path running in parallel, so that in each case a plurality of parallel transport paths are provided between feed devices having pick and place areas and pick and place heads assigned to them on both sides of the transport paths.

The invention being thus described, it will be obvious that the same may be varied in many ways. Such variations are not to be regarded as a departure from the spirit and scope of the invention, and all modifications as would be obvious to one skilled in the art are intended to be included within the scope of the following claims.

What is Claimed is:

1. A pick and place device for fitting substrates with components, comprising:
at least one feed device for feeding components to at least one collection position;
pick and place areas arranged on opposite sides of the feed device;
at least one pick and place head being positioned in each pick and place area, the at least one pick and place head being movable at least in a main direction of movement, and wherein the at least one pick and place head may retrieve components from the collection position;
at least one transport path, along which the substrates may be transported in a transport direction; and
at least one substrate holder assigned to each pick and place area, from which the substrates to be fitted may be picked up,
wherein the pick and place heads may transport the removed components to a predetermined fitting position to thereby place the removed components on the substrates being held by the substrate holders.

2. The pick and place device as claimed in claim 1, wherein the pick and place areas are arranged at the side of the transport path and along the main direction of movement corresponding to the transport direction, whereby it is possible for the substrates to be transported from the transport path to the pick and place areas by way of the substrate holders.

3. The pick and place device as claimed in claim 1, wherein two transport paths are provided, one of the two transport paths running through one of the pick and place areas and another of the two transport paths running through another of the pick and place areas, and wherein the substrate holders are formed by transport elements on the transport path, and the main direction of movement runs substantially at right angles to the transport direction.

4. The pick and place device as claimed in claim 1, wherein the feed device has a plurality of feed modules which are arranged parallel to one another and whose collection positions are arranged substantially along one path.

5. The pick and place device as claimed in claim 1, wherein the at least one pick and place heads is a plurality of pick and place heads being one of the types turret pick and place heads, matrix pick and place heads and row pick and place heads.

6. The pick and place device as claimed claim 1, wherein the at least one pick and place head is a plurality of pick and place heads being moveable substantially at right angles to the main direction of movement in addition to the main direction of movement.

7. A pick and place system having a plurality of pick and place devices arranged along a transport path and as claimed in claim 1, wherein feed devices are arranged between two pick and place areas and by way of pick and place heads of pick and place areas each facing the feed devices, it is possible for components to be removed from the feed devices and positioned on the substrates.

8. A method of fitting substrates with components by way of a pick and place device as claimed in claim 1, the method comprising:
alternatingly removing components from the collection position using pick and place heads assigned to one feed device; and
alternatingly positioning the components at the predetermined positions on the substrates.

9. The method as claimed in claim 8, wherein the components are positioned alternatingly at the predetermined positions on a substrate being located between two feed devices by way of pick and place heads assigned to two adjacent feed devices.

10. The pick and place device as claimed in claim 2, wherein the feed device has a plurality of feed modules which are arranged parallel to one another and whose collection positions are arranged substantially along one path.

11. The pick and place device as claimed in claim 3, wherein the feed device has a plurality of feed modules which are arranged parallel to one another and whose collection positions are arranged substantially along one path.

12. The pick and place device as claimed in claim 2, wherein the at least one pick and place is a plurality of pick and place heads being one of the types turret pick and place heads, matrix pick and place heads and row pick and place heads.

13. The pick and place device as claimed in claim 3, wherein the at least one pick and place is a plurality of pick and place heads being one of the types turret pick and place heads, matrix pick and place heads and row pick and place heads.

14. The pick and place device as claimed in claim 4, wherein the at least one pick and place is a plurality of pick and place heads being one of turret pick and place heads, matrix pick and place heads and row pick and place heads.
